(19) United States
(12) Patent Application Publication
(10) Pub. No.: US 2026/0324299 A1
(43) Pub. Date: Oct. 15, 2026

(54) A GRADIOMETRIC DEVICE AND AN ARRAY OF SUCH GRADIOMETRIC DEVICES

(71) Applicant: Technische Universiteit Delft, Delft (NL)

(72) Inventors: Marta Pita Vidal, Delft (NL); Arno Bargerbos, Delft (NL); Jaap Joachim Wesdorp, Delft (NL); Christian Kraglund Andersen, Delft (NL)

(73) Assignee: Technische Universiteit Delft, Delft (NL)

(21) Appl. No.: 19/484,882

(22) PCT Filed: May 17, 2024
(86) PCT No.: PCT/NL2024/050249

§ 371 Date: Nov. 17, 2025

(30) Foreign Application Priority Data
May 24, 2023 (NL) 2034903

(51) Int. Cl. H10N 60/12; H10N 60/80

(52) U.S. Cl. CPC H10N 60/12; H10N 60/805

(57) ABSTRACT

Provided herein is a gradiometric device having a patterned thin film structure on an insulating substrate and forming a loop on the substrate that has a first subloop connected to a second subloop by a twisted connection, a first element arranged within the first subloop and a second element arranged within the second subloop. The first and second subloops are arranged diagonally to each other, and the twisted connection is located at adjacent corners of the first and second subloops. The twisted connection has a base line element on the substrate running from the first subloop to the second subloop and a bridging line element at a level above the substrate crossing the base line element from the second subloop to the first subloop, the bridging line element separated from the base line element by an intermediate insulating layer. A first line portion holds the first element and is parallel to a second line portion that holds the second element.

The present application claims priority from the Dutch patent application No. 2034903, the content of which is incorporated herein by way of reference in its entirety.

### FIELD OF THE INVENTION

The present invention relates to a gradiometric device and to an array of gradiometric devices.

### BACKGROUND

In the field of superconducting qubits, superconducting circuits are created by connecting different circuit elements together. These circuit elements can be linear capacitors, linear inductors and non-linear inductors. As opposed to linear inductors, which have a quadratic energy-phase relationship, non-linear inductors have a non-quadratic energy-phase relationship. Well known non-linear inductors are superconducting-insulating-superconducting, SIS, Josephson junctions, with a cosinusoidal energy-phase relationship. Here, we will refer to any type of non-linear inductor as a Josephson element.

Many such superconducting circuits contain superconducting loops. A superconducting loop is defined when two inductive elements are connected in parallel. The magnetic flux thread through a loop sets a fixed relation between the superconducting phase drop across each of the two inductive elements. A superconducting loop containing one Josephson element connected in parallel to another inductive element is referred to as a superconducting quantum interference device (SQUID). If the Josephson element is connected in parallel to another non-linear Josephson element, the loop is referred to as a direct current (DC) SQUID. If the Josephson element is instead connected in parallel to a linear inductor, the loop is referred to as a radiofrequency (RF) SQUID. More generic circuit designs can contain multiple inductive elements in parallel, thus defining an array of multiple loops. Specifically, N inductive elements in parallel result in N-1 loops.

A traditional design for the implementation of RF or DC SQUIDs is that of single planar loops. These traditional loops are however highly sensitive to fluctuations of the perpendicularly applied global magnetic field, which results in fluctuations of the phase drop across the Josephson elements that form the loop. This high magnetic field sensitivity is detrimental to the performance of superconducting quantum devices. This is in particular a current challenge for the scalability of flux-tuneable transmon qubits, the most common superconducting qubit type. For current architectures, when multiple transmon qubits are placed in the same chip, each transmon is accompanied by one flux bias line that is used to tune the flux through the transmon SQUID loop. In an ideal scenario, each flux bias line should purely determine the flux threaded through the SQUID loop of its assigned transmon and it should not affect the flux through the SQUID loops of other transmons placed in the same chip. However, in practice, the fields induced by all flux bias lines on the chip affect the fluxes threaded through all transmons. This effect limits the coherence times of the qubits and adversely affects the systematic characterization of chips containing a large number of qubits.

For some qubit implementations, an alternative double-loop gradiometric design has been used in which a single Josephson element is shared by two loops. Such design can be used in a situation in which a Josephson element of interest is connected in parallel to a linear inductor, forming an RF SQUID. Examples of such qubits are flux qubits and fluxonium qubits. A double loop gradiometric design combats sensitivity to global magnetic field or noise by including a second symmetric loop with identical linear inductance and identical geometric area in parallel to the non-linear Josephson element. Such global magnetic field can be defined as a

magnetic field whose direction and magnitude do not vary within the area occupied by the loop. Equal magnetic fields through both loops result in identically opposite contributions to the phase drop across the Josephson element of interest, which cancel each other, resulting in a highly reduced sensitivity to global magnetic field or noise.

Moreover, a further disadvantage of both single planar and double planar loop prior art designs is the lack of scalability, i.e., single planar and double planar loops can not be coupled to loops of the respective same design to form larger superconducting circuits.

However, no analogous magnetic-field-insensitive loop design is available that can be used in the generic scenario of loops that include more than one Josephson element in parallel.

It is an object of the present invention to overcome or mitigate one or more of the disadvantages from the prior art.

### SUMMARY OF THE INVENTION

The object is achieved by a gradiometric device comprising a patterned thin film structure on an insulating substrate, the thin film structure forming a loop on the substrate, the loop comprising a first subloop and a second subloop, the first and second subloops interconnected by a twisted connection, a first element being arranged within the first subloop. Advantageously, the device constitutes an inductive loop design that is simultaneously insensitive to global magnetic field noise and compatible with circuit designs either containing more than two adjacent loops or where more than one Josephson element should be in parallel.

The proposed geometry consists of a single twisted loop which defines two subloops with identical area. The twisted geometry requires a cross-over of the loop over itself which provides a division of the first and second subloops within the loop.

According to an embodiment there is provided a gradiometric device wherein at least one second element is arranged within the second subloop.

According to an embodiment there is provided a gradiometric device wherein in the first subloop a line portion holding the first element is parallel to a line portion holding the at least one second element in the second subloop.

Additionally, the present invention relates to a gradiometric array comprising at least a first and second gradiometric device, each according to any one of the preceding claims, wherein the first gradiometric device is adjacent to the second gradiometric device, the second subloop of the first device connected to the first subloop of the second device such that in the array the second element of the first device and the first element of the second device coincide. Advantageously, the layout of the gradiometric device allows to scale up to superconducting circuits where a plurality of loops are interconnected in parallel in an array.

Advantageous embodiments are further defined by the dependent claims.

### BRIEF DESCRIPTION OF DRAWINGS

The invention will be explained in more detail below with reference to drawings in which illustrative embodiments thereof are shown. The Figures are meant for illustrative purposes only, and do not serve as restriction of the scope or the protection as laid down by the claims. FIG. 1A shows a perspective schematic view of a gradiometric device according to an embodiment of the invention;

FIG. 1B shows a schematic layout of the gradiometric device of FIG. 1A;

FIG. 2 shows a perspective schematic view of a gradiometric device according to an embodiment of the invention;

FIG. 3 shows a perspective schematic view of a gradiometric device according to an embodiment of the invention;

FIG. 4A shows a perspective schematic view of a gradiometric device according to an embodiment of the invention;

FIG. 4B shows a schematic layout of the gradiometric device of FIG. 4A;

FIG. 5A shows a schematic layout view of an array of gradiometric devices according to an embodiment of the invention;

FIG. 5B shows a schematic layout view of an array of gradiometric devices according to an embodiment of the invention ;

FIGS. 6A-6E show a schematic layout of gradiometric devices according to an embodiment of the invention.

In the drawings, identical or similar elements are indicated by the same reference sign or number.

### DETAILED DESCRIPTION OF EMBODIMENTS

The following is a description of certain embodiments of the invention, given by way of example only and with reference to the Figures.

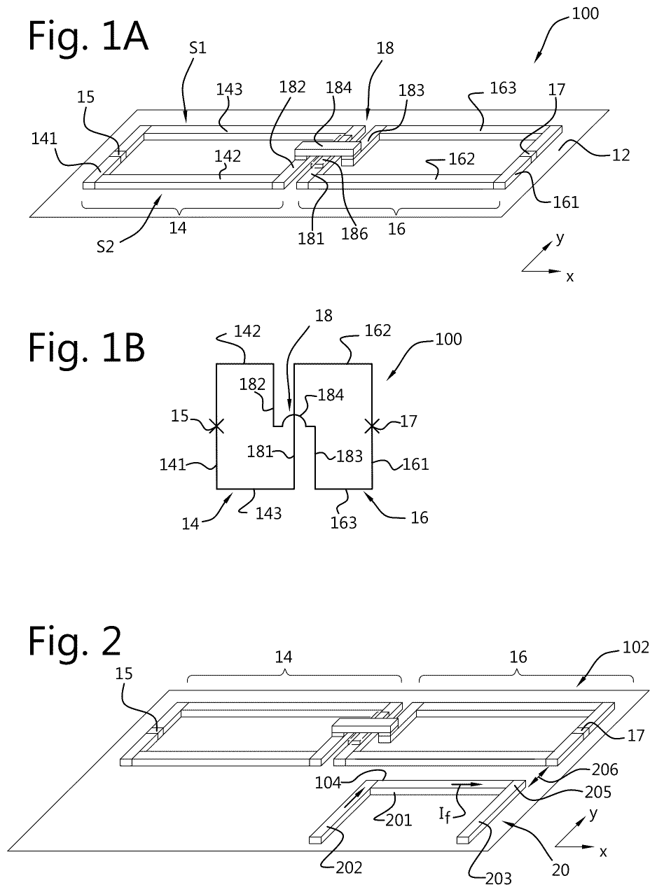

FIG. 1A shows a perspective schematic view of a gradiometric device according to an embodiment of the invention.

The gradiometric device 100 according to an embodiment comprises a closed loop disposed on a substrate 12. The closed loop typically consists of a superconductor material, and the substrate 12 comprises at least an insulating surface layer.

In an exemplary embodiment, the loop has a substantially rectangular shape extending in orthogonally first and second directions X and Y and comprises a first and second rectangular subloop 14,16. The first and second subloops 14,16 are adjacent to each other along the first direction X of the rectangle. To create the closed loop, the first and second subloops are interconnected with a twisted connection 18 centrally located therebetween 14,16. The twisted connection comprises a first connection line that connects one leg of the first subloop to one leg of the second subloop and a second connection line that connects the other leg of the first subloop to the other leg of the second subloop, in a manner that the second connection line crosses over the first connection line. The cross-over provides a division of the first and second subloops within the loop:

In the design according to the embodiment, each subloop 14; 16 comprises a frame with a main line portion 141; 161 extending in the second direction Y perpendicular to the first direction X, and two legs 142,143; 162,163 parallel to each other that each are extending in the first direction X from a respective end of the main line portion 141; 161 in each subloop 14; 16 towards the centrally arranged twisted connection 18 between the subloops. At the twisted connection a first connecting line 181 connects one leg 143 of the first subloop 14 at a first side S1 thereof to one leg 162 of the second subloop 16 at a second side S2 opposite to the first side S1. Likewise, a second connecting line 182,184,183 connects the other leg 142 of the first subloop 14 at the second side S2 thereof to the other leg 163 of the second subloop 16 at the first side S1.

The second connecting line 182,184,183 comprises a bridging portion 184 or bridging element raised above the substrate surface relatively to the first connection line such that the bridging portion 184 crosses the first connecting line 181 to create the twisted connection 18, preferably halfway the first connecting line. The bridging portion 184 of superconducting material is electrically isolated from the first connecting line 181 by an intermediate insulating layer 186 to avoid a short circuit in the twisted connection.

The first and second subloops 14, 16 have a substantially identical shape with a same area size. Similarly to a double loop planar gradiometric design, during operation, the contribution of a global magnetic field to a current through each of the two subloops exactly cancels, rendering the loop insensitive to global magnetic noise. A global magnetic field applied perpendicular to the loop plane (here: the substrate surface) results on a substantially equal magnetic flux threaded through each of the two subloops 14, 16. If the area of the two subloops 14,16 is equal, the two magnetic fluxes will be equal. Each of the two magnetic fluxes will generate a supercurrent through the loop with equal magnitude but opposite direction. As a result, the net current on the loop generated by any global magnetic field on the loop will be zero, rendering the loop insensitive to global magnetic field variations.

In the embodiment of FIG. 1A, the first subloop 14 comprises a first inductive element 15 and the second subloop 16 comprises at least one second inductive element 17. The inductive elements 15,17 are Josephson elements. In an embodiment, the first and at least one second inductive elements 15,17 are arranged such that in the first subloop 14 the main line portion 141 holding the first inductive element 15 is parallel to the main line portion 161 holding the at least one second inductive element 17 in the second subloop 16.

In an alternative embodiment, only the first subloop 14 comprises a first inductive element 15, which is a Josephson element. The second subloop 16 does not contain a inductive element.

The subloops 14,16 of the gradiometric device may have a length within a range of about 10-1000 μm and a width between about 50 and 1000 nm.

The line portions 141,161, connecting lines 181, 182, 183, 184 and legs 142, 143, 162, 163 of the subloops 14,16 may have a line width of about 2-200 μm and a line thickness of about 5-500 nm.

The one or more inductive elements may comprise a stack of Al/Al₂O₃/Al. but other superconductor/insulator/superconductor, SIS, or superconductor/semiconductor/superconductor, SNS, stacks can be used as will be appreciated by the skilled in the art. The thickness or length of the insulating or semiconducting material of the inductive element is typically 1-200 nm.

FIG. 1B shows a schematic layout of the gradiometric device of FIG. 1A.

It will be appreciated that the layout of the loop and/or subloops is not limited to a rectangle. The skilled in the art to which the invention belongs, will appreciate that other layouts can be used within the scope of the invention as claimed.

FIG. 2 shows a perspective schematic view of a gradiometric device 102 according to a further embodiment of the invention.

In this embodiment, the gradiometric device 102 comprises the same elements as described with reference to FIGS. 1A and 1B. in addition, the gradiometric device 102 comprises a conductor line disposed 20 on the substrate 12. The conductor line comprises a conductor line portion 201 that extends adjacent, optionally parallel, to a neighboring one of the legs of one subloop (as shown here the leg 162 of the second subloop 16), and a pair of connecting wires 202,203 each respectively attached at an end 204,205 of the conductor line portion 201. The conductor line portion 201 is separated from the neighboring leg 162 of the second subloop by a gap 206. The conductor line portion 201 during operation functions as a flux generating line that by a current If generates a magnetic flux that interacts with the second subloop 16. As such, a supercurrent flowing through the loop can be adjusted.

The gap 206 may have a width within a range of about 0.5 μm to about 10 μm.

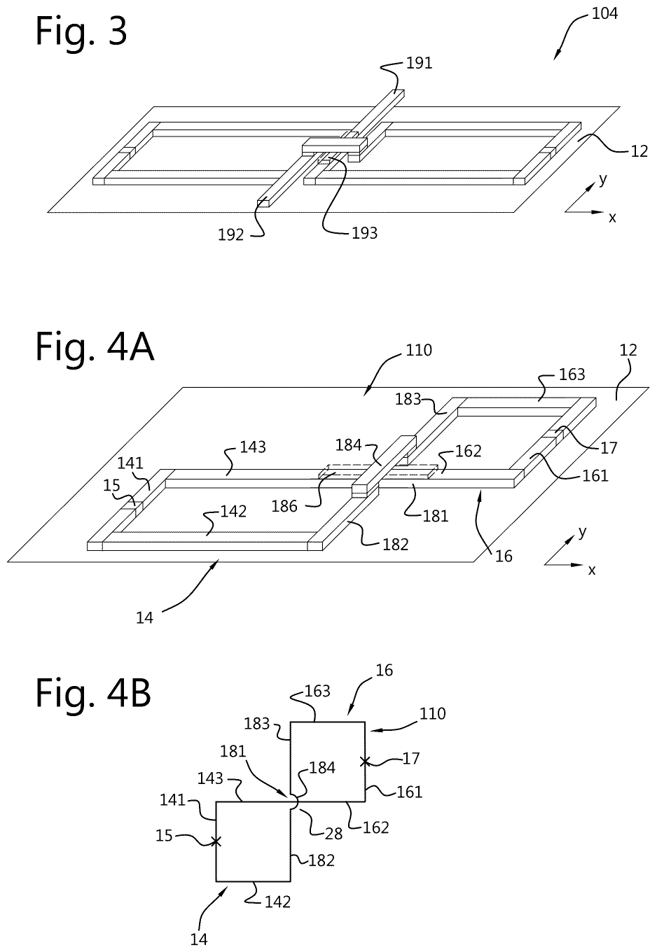

FIG. 3 shows a perspective schematic view of a gradiometric device 104 according to a further embodiment.

In this embodiment, the gradiometric device 104 comprises the same elements as described with reference to FIGS. 1A and 1B and optionally also the elements as described with reference to FIG. 2.

In the gradiometric device 104 according to the embodiment, nodal line portions 191,192 are provided that can be used to couple the gradiometric device 104 to a neighboring device (not shown). The neighboring device may be of same or similar design or layout.

The gradiometric device 104 comprises a first nodal line portion 191 connected to the loop between the first 15 and the at least one second inductive element 17 in a first path from the first subloop 14 to the second subloop 16, and a second nodal line portion 192 connected to the loop between the first 15 and the at least one second inductive element 17 in a second path from the second subloop 16 to the first subloop 14.

In a further embodiment, one of the first and second nodal line portions 191; 192 is connected to the first connecting line 181 of the twisted connection 18 and the other of the nodal line portions 191; 192 is connected to the second connecting line 182,184,183 of the twisted connection 18.

FIG. 4A shows a perspective schematic view of a gradiometric device 110 according to an embodiment of the invention.

In this embodiment, the gradiometric device 104 comprises the same elements as described with reference to FIGS. 1A and 1B and optionally also the elements as described with reference to FIGS. 2 and 3.

In an alternative design the first and second subloops 14,16 of the gradiometric device are arranged diagonally relative to each other. In this arrangement, a twisted connection 28 between the first and second subloops 14,16 is provided at the location of the adjacent corners of the subloops 14,16.

Similar as in the embodiment shown above, at the twisted connection 28 a first connecting line 181, connects one leg 143 of the first subloop 14 to one leg 162 of the second subloop 16 at the adjacent corners. Likewise, a second connecting line 182,185,183 connects the other leg 142 of the first subloop 14 to the other leg 163 of the second subloop 16. The second connecting line 182,185,183 comprises the bridging portion 185 or bridging element that crosses the first connecting line 181 to create the twisted connection 28. The bridging portion 185 is electrically isolated from the first connecting line 181 by an intermediate insulating layer.

Each subloop 14; 16 comprises at least one inductive element 15; 17 in the respective main line portion 141; 161. The inductive element may be a Josephson element.

FIG. 4B shows a schematic layout of the gradiometric device as shown in FIG. 4A.

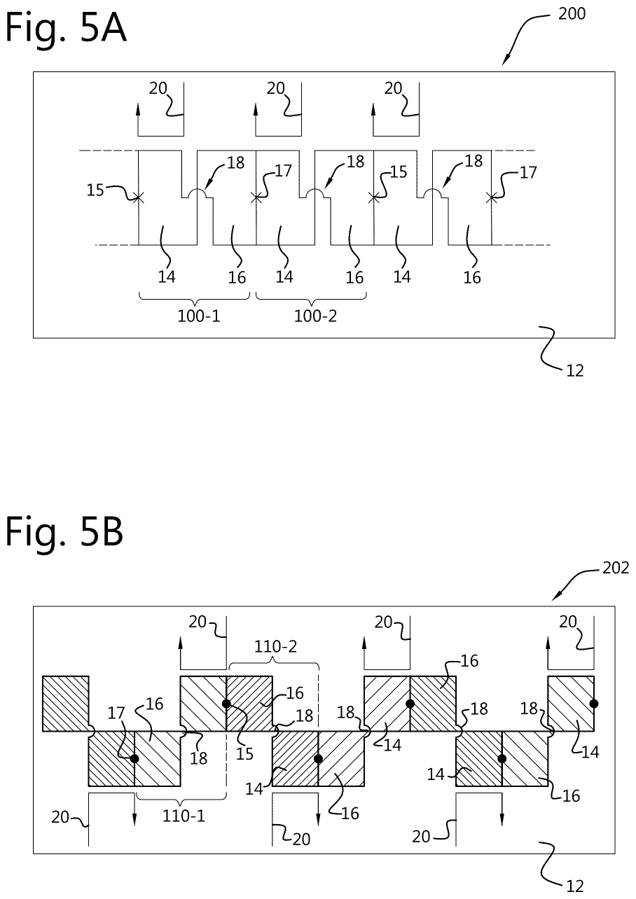

FIG. 5A shows a schematic layout view of an array 200 of gradiometric devices according to an embodiment of the invention.

The concept of the twisted loop layout of the gradiometric device 100; 102; 104; 110 as described above allows to scale up to superconducting circuits where a plurality of loops are interconnected in parallel in an array.

As an example in FIG. 5A, an array 200 is shown constructed from a plurality of gradiometric devices 100 with in each gradiometric device 100 the first and second subloops 14,16 of the gradiometric device are arranged lengthwise relative to each other.
in FIG. 5B an array 202 is shown constructed from a plurality of gradiometric devices 110 with in each gradiometric device 110 the first and second subloops 14,16 of the gradiometric device are arranged diagonally relative to each other.

As shown in FIGS. 5A, 5B, the gradiometric devices are arranged with a first gradiometric device 100-1; 110-1 adjacent to a second gradiometric device 100-2; 110-2. In the first gradiometric device a subloop 14 holding a first inductive element 15 is connected to a subloop 16 of the second gradiometric device, in a manner that the first inductive element 15 is common to the subloop 14 of the first gradiometric device and the subloop 16 of the second gradiometric device.

In other words, the array 200; 202 has an interface where a subloop of the first device comprising a first inductive element is connected to a subloop of the second device comprising a second inductive element, in a manner that in the array the first inductive element of the first device and the second inductive element of the second device coincide, i.e., the first gradiometric device and the second gradiometric device share an inductive element at said interface.

The array 200; 202 can contain at least two gradiometric devices connected as described.

Each gradiometric device 100-1; 100-2; 110-1; 110-2 in the array 200 can be provided with a conductor line 20 parallel to one of the subloops of the gradiometric device, as described with reference to FIG. 2 above.

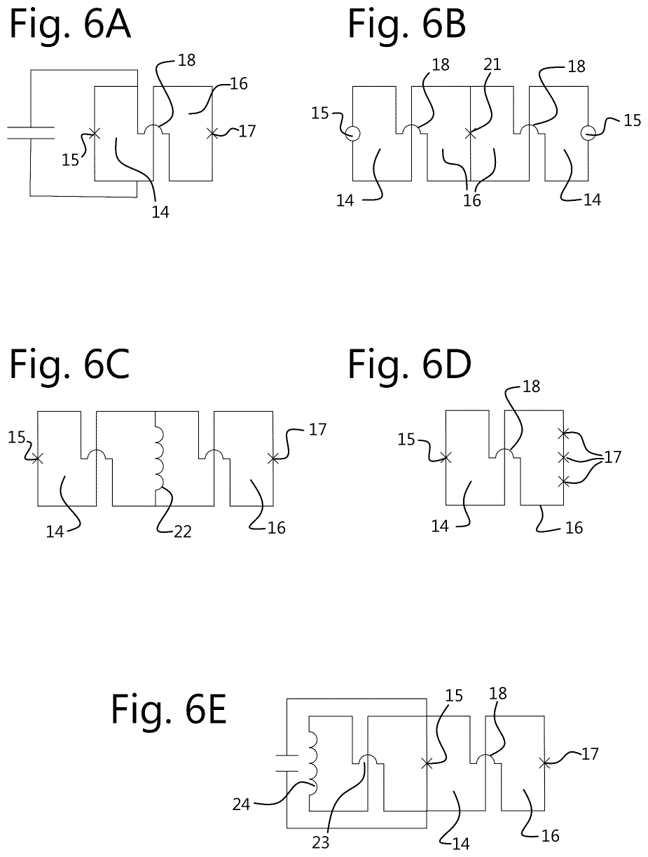

FIGS. 6A-6E show schematic layouts of gradiometric devices according to an embodiment of the invention.

The twisted loop design can be implemented in accordance with the invention in a variety of superconducting circuits which each comprise one or more loops, each implemented with two subloops that are interconnected by means of a twisted connection.

FIG. 6A shows a schematic of a flux-tuneable transmon circuit comprising two identical SIS Josephson inductive elements 15,17 in parallel (a DC SQUID). FIG. 6B shows a schematic of two coupled Andreev spin qubits that contain two non-linear Josephson elements 15 and an SIS or SNS Josephson element 21 in parallel, defining two loops.

FIG. 6C shows a schematic of so-called ATS (asymmetrically threaded SQUID), a component for the realization of bosonic cat qubits, comprising two SIS Josephson inductive elements 15,17 and a linear inductor 22 in parallel, forming two loops.

FIG. 6D shows a schematic of a so-called SNAIL (Superconducting Nonlinear Asymmetric Inductive element), a basic component of some parametric amplifiers and couplers, comprising a subloop 14 with one SIS Josephson junction 15 and a subloop 16 comprising an array of three larger SIS Josephson junctions 17 connected in parallel by a twisted connection 18.

FIG. 6E shows a schematic of a flux-tuneable fluxonium comprising two subloops 14; 16 each comprising a SIS Josephson junction 15; 17 and a linear inductor 24 in which the subloops 14,16 are connected by a twisted connection 18 in accordance with an embodiment. Additionally, the linear inductor 24 is connected to one of the subloops 14 by a second twisted connection 23. As such two loops are defined.

The invention has been described with reference to a number of exemplary embodiments as shown in the drawings. The scope of the invention is therefore defined by the appended claims rather than by the foregoing description. It will be apparent to the person skilled in the art that alternative and equivalent embodiments of the invention can be conceived and reduced to practice. All changes which come within the meaning and range of equivalency of the appended claims are to be embraced within their scope.

General aspects of the present disclosure are summarized in the following clauses 1-18.

1. A gradiometric device comprising a patterned thin film structure on an insulating substrate, the thin film structure forming a loop on the substrate, the loop comprising a first subloop and a second subloop, the first subloop connected to the second subloop by a twisted connection, a first element being arranged within the first subloop.

2. The gradiometric device according to clause 1 wherein at least one second element is arranged within the second subloop.

3. The gradiometric device according to clause 2, wherein in the first subloop a line portion holding the first element is parallel to a line portion holding the at least one second element in the second subloop.

4. The gradiometric device according to any one of clauses 1-3, wherein the first element is an inductive element.

5. The gradiometric device according to any one of clauses 2-3, wherein the first element is an inductive element.

6. The gradiometric device according to any of the preceding clauses, wherein each of the subloops is configured to surround an area of substantially same size on the substrate.

7. The gradiometric device according to any one of the preceding clauses, wherein the loop has a layout formed by interconnected line elements.

8. The gradiometric device according to any one of the preceding clauses, wherein the first and second subloops each have a layout formed by interconnected line elements.

9. The gradiometric device according to clause 5 or 6, wherein the layout has a rectangular shape.

10. The gradiometric device according to according to any one of the preceding clauses, wherein the first and second subloops are arranged in line with each other, the twisted connection located intermediate the first and second subloops.

11. The gradiometric device according to according to any one of the preceding clauses, wherein the first and second subloops are arranged diagonally to each other, the twisted connection located at adjacent corners of the first and second subloops.

12. The gradiometric device according to clause 10 or 11, wherein the twisted connection comprises a base line element located on the substrate running from the first subloop to the second subloop and a bridging line element at a level above the substrate crossing the base line element from the second subloop to the first subloop, the bridging line element being separated from the base line element by an intermediate insulating layer.

13. The gradiometric device according to any one of the preceding clauses, wherein the loop consists of a superconductor material.

14. The gradiometric device according to any one of the preceding clauses 2-13, wherein each inductive element is a Josephson element.

15. The gradiometric device according to any one of the preceding clauses, wherein adjacent to a leg of the first subloop a conductor line is arranged; the conductor line separated from the leg by a gap.

16. The gradiometric device according to any one of the preceding clauses, wherein the gradiometric device comprises a first nodal line portion connected to the loop between the first and the at least one second inductive element in a first path from the first subloop to the second subloop, and a second nodal line portion connected to the loop between the first and the at least one second inductive element in a second path from the second subloop to the first subloop.

17. A gradiometric array comprising at least a first and second gradiometric device, each according to any one of the preceding clauses, wherein the first gradiometric device is adjacent to the second gradiometric device, the second subloop of the first device connected to the first subloop of the second device such that in the array the second element of the first device and the first element of the second device coincide.

18. The array according to clause 17 being scalable by arranging a plurality of gradiometric devices adjacent to each other such that in the array the second element of one gradiometric device from the plurality and the first element of a next gradiometric device from the plurality adjacent to the one gradiometric device coincide.

1. A gradiometric device comprising a patterned thin film structure on
an insulating substrate, the thin film structure forming a loop on the substrate, the loop comprising a first subloop and a second subloop the first subloop connected to the second subloop by a twisted connection a first element being arranged within the first subloop and a second element being arranged within the second subloop,
wherein the first and second subloops are arranged diagonally to each other, the twisted connection located at adjacent corners of the first and second subloops,
wherein the twisted connection comprises a base line element located on the substrate running from the first subloop to the second subloop and a bridging line element at a level above the substrate crossing the base line element from the second subloop to the first subloop, the bridging line element being separated from the base line element by an intermediate insulating layer,
wherein in the first subloop a first line portion holding the first element is parallel to a second line portion holding the second element in the second subloop.

2. The gradiometric device according to claim 1, wherein at least one of the first element and the second element is an inductive element.

3. (canceled)

4. The gradiometric device according to claim 1, wherein each of the subloops is configured to surround an area of substantially same size on the substrate.

5. The gradiometric device according to claim 1, wherein the loop has a layout formed by interconnected line elements.

6. The gradiometric device according to claim 1, wherein the first and second subloops each have a layout formed by interconnected line elements.

7. The gradiometric device according to claim 5, wherein the layout has a rectangular shape.

8. The gradiometric device according to claim 1, wherein the loop consists of a superconductor material.

9. The gradiometric device according to claim 2, wherein each inductive element is a Josephson element.

10. The gradiometric device according to claim 1, wherein adjacent to a leg of the first subloop a conductor line is arranged; the conductor line separated from the leg by a gap.

11. The gradiometric device according to claim 2, further comprising a first nodal line portion connected to the loop between the first and the second inductive element in a first path from the first subloop to the second subloop, and a second nodal line portion connected to the loop between the first and the second inductive element in a second path from the second subloop to the first subloop.

12. A gradiometric array comprising at least two of the gradiometric device according to claim 1, the at least two gradiometric devices comprising first and second gradiometric devices,
wherein the first gradiometric device is adjacent to the second gradiometric device, the second subloop of the first device connected to the first subloop of the second device such that in the array the second element of the first device and the first element of the second device coincide.

13. The array according to claim 12 being scalable by arranging a plurality of gradiometric devices adjacent to each other such that in the array the second element of one gradiometric device from the plurality and the first element of a next gradiometric device from the plurality adjacent to the one gradiometric device coincide.
